(19) United States
(12) Patent Application Publication
(10) Pub. No.: US 2008/0111709 A1
(43) Pub. Date: May 15, 2008

(54) Data input arrangement with clustering arrangement scheme

(76) Inventors: Chad Chaumont, East Setauket, NY (US); Shane MacGregor, Forest Hills, NY (US); Alistair Hamilton, Stony Brook, NY (US)

Correspondence Address: FAY KAPLUN & MARCIN, LLP, 150 BROADWAY, SUITE 702, NEW YORK, NY, 10038, US

(21) Appl. No.: 11/618,963

(22) Filed: Jan. 2, 2007

Related U.S. Application Data
(60) Provisional application No. 60/863,272, filed on Oct. 27, 2006.

(51) Int. Cl. H03M 11/00

(52) U.S. Cl. 341/22

(57) ABSTRACT

A data input arrangement for a mobile device which includes a first group of input keys, a second group of input keys and a break. The first group defines a first typing surface on the mobile device. The first typing surface defines a first shape. The second group defines a second typing surface on the mobile device. The second typing surface defines a second shape different from the first shape. The break is situated between the first and second groups to separate the first and second groups from one another.

### PRIORITY CLAIM

This application claims the priority to the U.S. Provisional Application Ser. No. 60/863,272, entitled “Data Input Arrangement With Clustering Arrangement Scheme,” filed Oct. 27, 2006. The specification of the above-identified application is incorporated herewith by reference.

### FIELD OF THE INVENTION

The present invention relates generally to a data input arrangement with an arrangement whereby keys are clustered.

### BACKGROUND

Computing devices include a data input arrangement that allows a user to enter data. Conventional data input arrangements include keys with a corresponding data input. Conventional data input arrangements with, for example, key pad 10 as shown in FIG. 1 are designed to minimize a total surface area with which the keys occupy. The minimization of the total surface area allows manufacturers to decrease the overall size of mobile devices. However, by creating one large cluster of keys to occupy a small area, users are forced to always view the key pad 10 in order to utilize it. Furthermore, if a user were to blindly touch the key pad 10, no relative position on the key pad 10 is identifiable.

### SUMMARY OF THE INVENTION

The present invention relates to a data input arrangement for a mobile device. The data input arrangement may include a first group of input keys, a second group of input keys and a break. The first group defines a first typing surface on the mobile device. The first typing surface defines a first shape. The second group defines a second typing surface on the mobile device. The second typing surface defines a second shape different from the first shape. The break is situated between the first and second groups to separate the first and second groups from one another.]

### DESCRIPTION OF THE DRAWINGS

FIG. 1 shows a conventional data input arrangement for a computing device.

FIG. 2 shows a data input arrangement for a computing device according to an exemplary embodiment of the present invention.

FIG. 3 shows a perspective view for a second exemplary embodiment of a clustering arrangement scheme for the data input arrangement of FIG. 2.

FIG. 4 shows a perspective view for a third exemplary embodiment of a clustering arrangement scheme for the data input arrangement of FIG. 2.

FIG. 5 shows a perspective view for a fourth exemplary embodiment of a clustering arrangement scheme for the data input arrangement of FIG. 2.

FIG. 6 shows a perspective view for a fifth exemplary embodiment of a clustering arrangement scheme for the data input arrangement of FIG. 2.

### DETAILED DESCRIPTION

The present invention may be further understood with reference to the following description and the appended drawings, wherein like elements are referred to with the same reference numerals. The present invention describes a data input arrangement for a computing device (e.g., personal computer, laptop, pager, mobile device, cell phone, radio frequency identification device, scanner, a data acquisition device, an imager, etc.). According to the exemplary embodiments of the present invention, the data input arrangement may exhibit a clustering arrangement scheme. The data input arrangement and the clustering arrangement scheme will be discussed in more detail below.

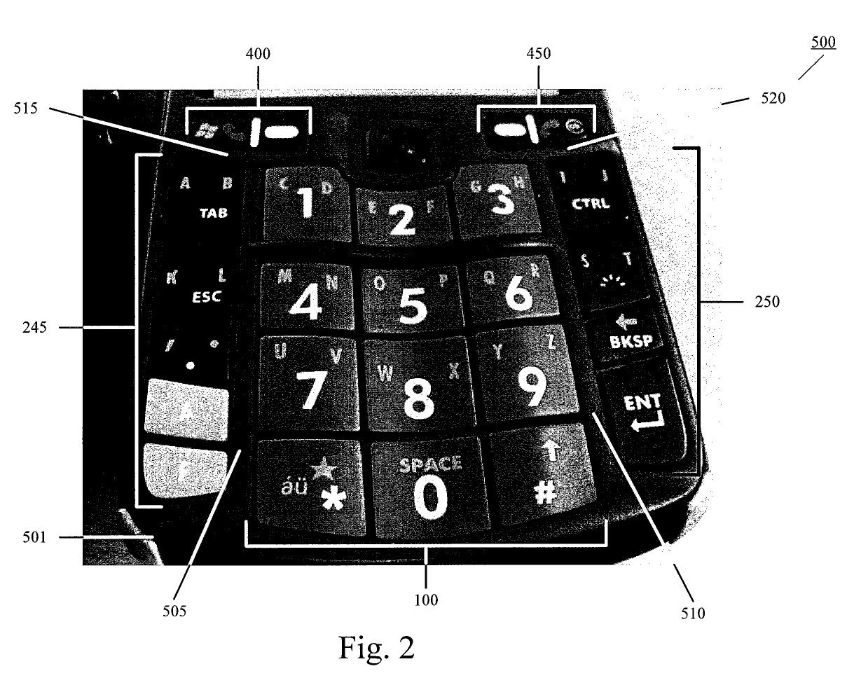

FIG. 2 shows a data input arrangement 500 for a computing device according to an exemplary embodiment of the present invention. Specifically, FIG. 2 illustrates the computing device as a mobile device. It should be noted that the use of a mobile device is only exemplary and, as discussed above, the data input arrangement 500 may be applied to any computing device utilizing a data input arrangement. In the following exemplary embodiments, the data input arrangement 500 is described using a key pad for a mobile device. However, the data input arrangement 500 may be any arrangement with a typing surface that utilizes one or more keys to input data such as a data-centric key pad, numeric key pad, keyboard, etc. It should be noted that the use of keys is only exemplary and the data input arrangement may utilize other data input means such as switches, light sensors, heat sensors, etc.

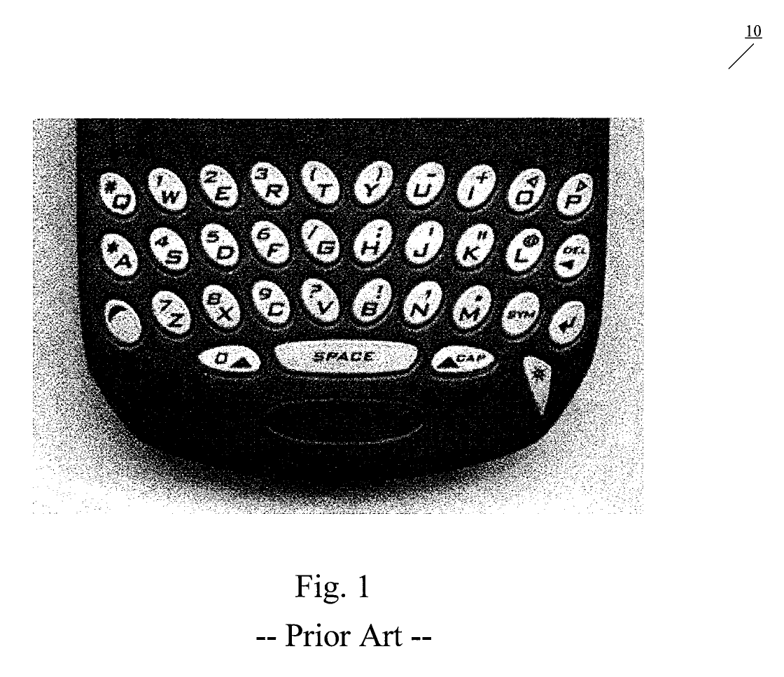

Referring to FIG. 2, the data input arrangement 500 utilizes a clustering arrangement scheme for arranging the keys on the data input arrangement 500. The data input arrangement 500 may include a plurality of groups of input keys (e.g., a numeric key pad 100, function key pads 245, 250, and communication key pads 400, 450). In contrast, conventional mobile devices utilize, for example, the conventional key pad 10 shown in FIG. 1. The conventional key pad 10 contains no separation of keys (i.e., no groups).

In the exemplary embodiment, the keys of the numeric key pad 100 may input numeric data (e.g., the numbers “0”-“9”, “*”, and “#”). The keys of the numeric key pad 100 may also input letter data (e.g., “c”, “d”, “e”, “f”, etc.). For example, the key “1” may also be used to input the letters “C” and “D”; the key 2 may also be used to input the letters “E” and “F”; etc.

The keys of the function key pads 245, 250 are used for further inputs of the key pad. The function key pad 245 may include keys for TAB, ESC, ALPHA/FUNCTION, etc. The ALPHA/FUNCTION keys may be used to switch between the primary input data and the secondary input data of the other keys. For example, the ALPHA key may be pressed so a user may input secondary data. The FUNCTION key may be pressed so a user may input primary data. It should be noted that the use of two separate keys to switch between primary and secondary input data is only exemplary and a single button may be used. The function key pad 250 may include keys for CTRL, BKSP, ENTER, etc.

The keys of the communication key pads 400, 450 are used for inputs regarding telephone functions associated with the mobile device. For example, the keys of the communication key pad 400 may answer incoming calls, dial/redial outgoing calls, switch between multiple lines, etc. The keys of the communication key pad 450 may decline incoming calls, hang up a line, etc.

In the exemplary embodiment illustrated in FIG. 2, the groups of input keys (e.g., numeric key pad 100, function key pads 245, 250, and communication key pads 400, 450) are separated using breaks. For example, a break 505 exists between the numeric key pad 100 and the function key pad 245; a break 510 exists between the numeric key pad 100 and the function key pad 250; a break 515 exists between the function key pad 245/numeric key pad 100 and the communication key pad 400; and a break 520 exists between the numeric key pad 100/function key pad 250 and the communication key pad 450. The breaks 505-520 are additional pieces of the molding of the mobile device. The breaks 505-520 may be inserted after the molding of the mobile device is manufactured, thereby making them attachable/releasable. The molding of the mobile device may be manufactured with the breaks 505-520 (e.g., as part of the casting mold), thereby making them permanent. To facilitate a more convenient operating area for the user, the breaks 505-520 have an identical width. That is, the groups 100, 245, 250, and 400/450 are evenly spaced apart.

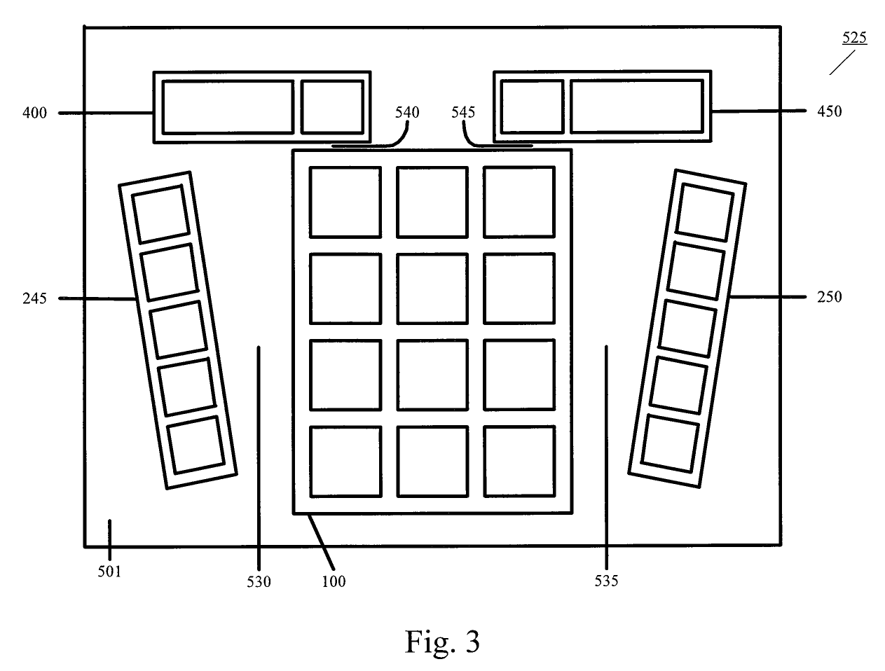

It should be noted that the even spacing is only exemplary and the breaks 505-520 may have varying widths that further makes utilizing the data input arrangement 500 more convenient for the user. For example, FIG. 3 illustrates an exemplary embodiment 525 of a clustering arrangement scheme for the data input arrangement 500. In this exemplary embodiment, the data input arrangement 500 also includes a plurality of groups (e.g., the numeric key pad 100, the function key pads 245, 250, the communication key pads 400, 450). However, as shown in FIG. 3, the breaks 530-545 exhibit varying widths. The angled disposition of the function key pads 245, 250 in relation to the aright disposition of the numeric key pad 100 creates a tapering longitudinally. Thus, the breaks 530, 535 have a larger width towards the top and a smaller width towards the bottom of the data input arrangement 500. The breaks 540, 545 have a uniform width extending laterally across the data input arrangement 500. However, the width of the breaks 540, 545 is substantially smaller than the smallest width exhibited by the breaks 530, 535.

It should be noted that the use of uniform widths through each break, identical widths among all the breaks, and varying widths through each break is only exemplary. Those skilled in the art will understand that the breaks that separate the groups of the data input arrangement 500 may exhibit more than one of the above-described characteristics and may also exhibit a curvature, an elevation, a depression, a texture (e.g., bumps, ridges, lines, etc.), a coating (e.g., leather, cloth, rubber, etc.), etc. In addition, the data input arrangement 500 may include more or fewer breaks depending on the arrangement and number of the groups.

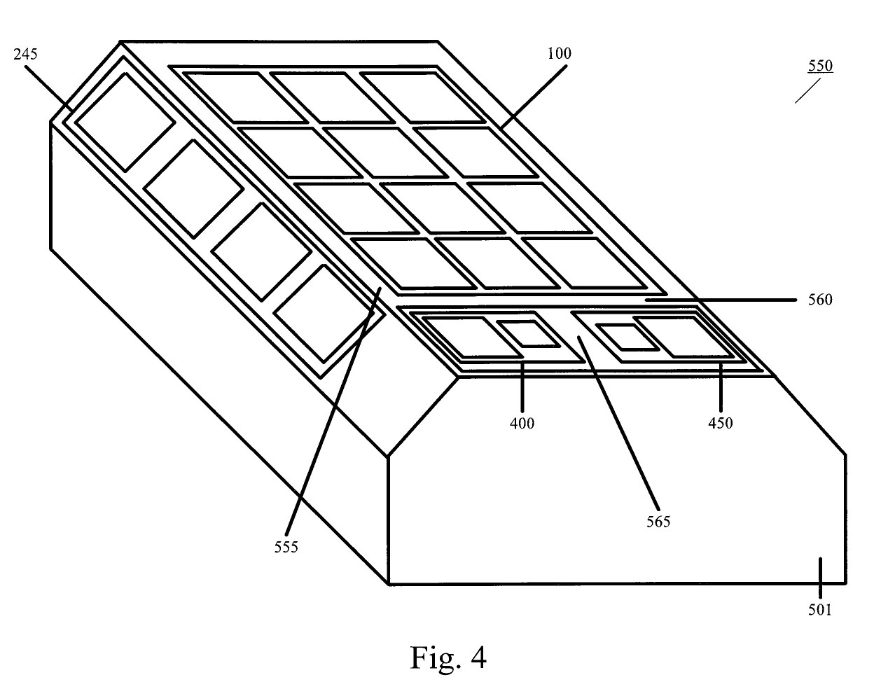

FIG. 4 shows another exemplary embodiment 550 of a clustering arrangement scheme for the data input arrangement 500. In this exemplary embodiment, the data input arrangement 500 is not flat. That is, certain groups exist on a different plane than the other groups. For example, as illustrated, the numeric key pad 100 and the communication key pads 400, 450 exist on the same plane. However, the function key pad 245 is on an angled plane. In this exemplary embodiment, a break 560 separates the numeric key pad 100 with the communication key pads 400, 450. A break 565 separates the communication key pad 400 from the communication key pad 450. As discussed above, the breaks 560 and 565 exhibit uniform widths, although they may taper or be identical. In addition, a break 555 separates the numeric key pad 100 from the function key pad 245. The break 555 may be angled to support the separation of the groups existing on different planes. As illustrated, the break 555 exhibits a decreasing angle so that the function key pad 245 exists relatively lower than the numeric key pad 100. The decreasing angled plane of the function key pad 245 is another form of the cluster arrangement scheme.

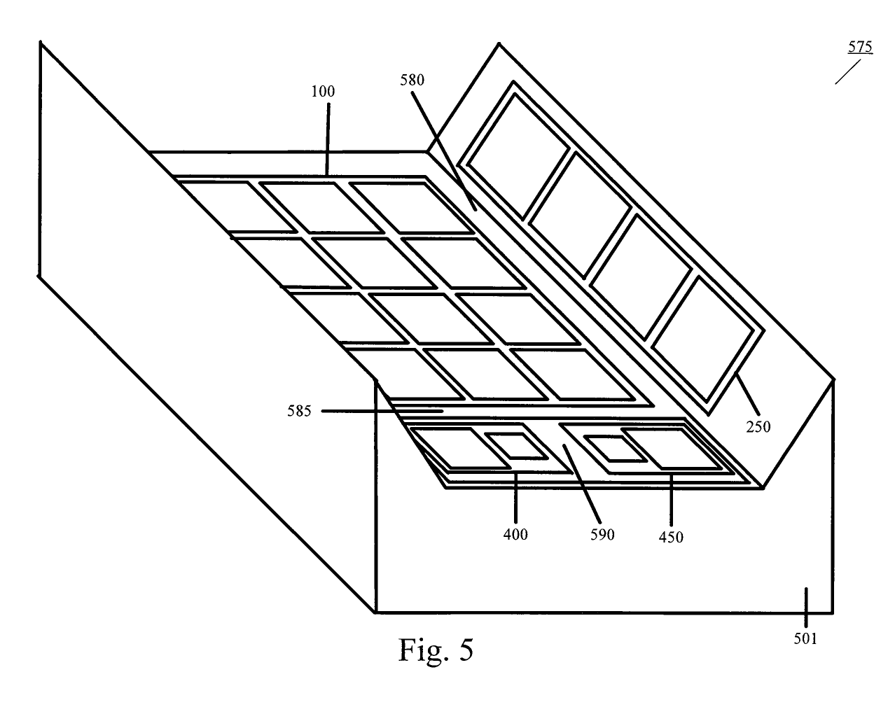

FIG. 5 shows another exemplary embodiment 575 of a clustering arrangement scheme for the data input arrangement 500. In this exemplary embodiment, the data input arrangement 500 is also not flat. That is, certain groups exist on a different plane than the other groups. Specifically, the relative angle with which the data input arrangement 500 exhibits is an opposite orientation from the exemplary embodiment 550 of FIG. 4. For example, as illustrated, the numeric key pad 100 and the communication key pads 400, 450 exist on the same plane separated by a break 585. A break 590 separates the communication key pad 400 from the communication key pad 450. It should be noted that the breaks 585 and 590 exhibit uniform widths, although they may taper or be identical. A break 580 separates the numeric key pad 100 from the function key pad 250. As illustrated, the break 580 exhibits an increasing angle so that the function key pad 250 exists relatively higher than the numeric key pad 100. The increasing angled plane of the function key pad 250 is another form of the cluster arrangement scheme. Those skilled in the art will appreciate that the increasing angled plane orientation may provide a sheltering arrangement. That is, the increasing angled planes create walls that may prevent, for example, the keys from being damaged.

The groups (e.g., numeric key pad 100, function key pads 245, 250, and communication key pads 400, 450) may also be color coordinated to further facilitate convenient operation of the mobile device. For example, the numeric key pad 100 may exhibit a light gray shade. The function key pads 245, 250 may exhibit a black shade. The communication key pads 400, 450 may exhibit a dark gray shade. It should be noted that the use of shades is only exemplary and the groups may be color coordinated using different colors (e.g., red, yellow, blue). The color coordination scheme allows a user to easily identify a key(s) (i.e., group) from a simple glance at the key pad arrangement 500.

Each group of the key pad arrangement 500 may exhibit a uniform shape. For example, in reference to FIG. 2, the numeric key pad 100 has a wave shape with two crests (e.g., at columns 1 and 3) and one trough (e.g., at column 2). All keys of the numeric key pad 100 exhibits this wave shape. The function key pads 245, 250 may use an angled shape. In the exemplary embodiment, the function key pad 245 is slightly elevated toward the left side of the keys (i.e., by the left edge of the mobile device) and extends substantially linearly down across each key (i.e., toward the left edge of the numeric key pad 100). The function key pad 250 is slight elevated toward the right side of the keys (i.e., by the right edge of the mobile device) and extends substantially linearly down across each key (i.e., toward the right edge of the numeric key pad 100). The communication key pads 400, 450 are substantially linear across the keys with no angle. The consistent shape of the keys for each group allows a user to blindly identify a key or group of keys for each group from a simple touch of the key pad arrangement 500. However, it should be noted that the cluster arrangement scheme still allows all the keys of each group to exhibit identical shapes.

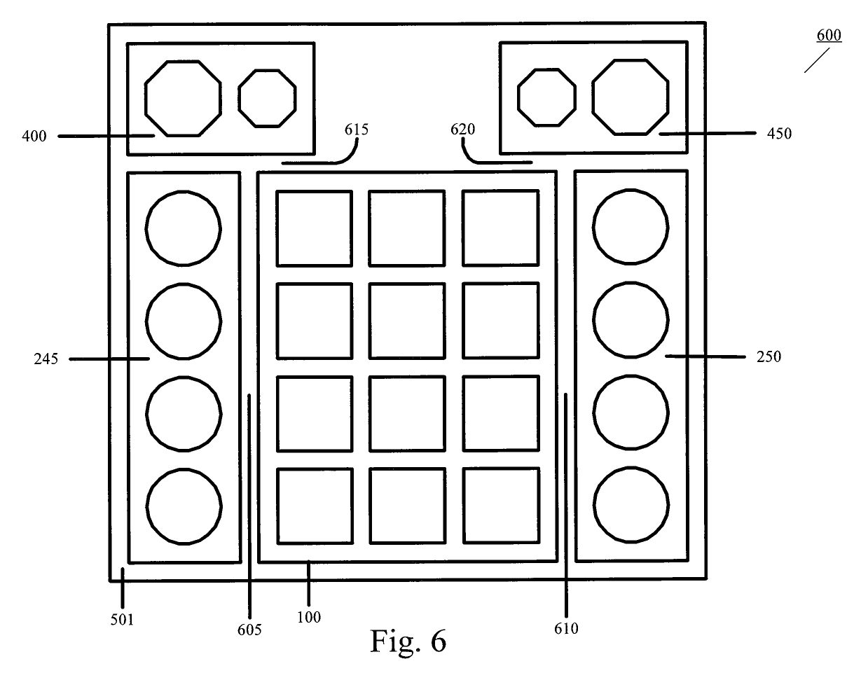

In another embodiment, the keys of a group may exhibit the same shape. For example, FIG. 6 shows a perspective view for a fifth exemplary embodiment 600 of a clustering arrangement scheme for the data input arrangement 500 of FIG. 2. In the exemplary embodiment, the keys of the numeric key pad 100 may be square shaped, the keys of the function key pads 245, 250 may be circular shaped, and the keys of the communication key pads 400, 450 may be octagonal. By maintaining a common shape for each key of a group and further using different shapes for each group, a user may identify the group more conveniently. Furthermore, the use of different shapes allows the manufacture of identical breaks between each group. For example, the breaks 605-620 exhibit uniformity and are also of uniform width. The lengths of the breaks 605-620 are different to accommodate for the differing lengths of the sections with which the breaks 605-620 respectively separate. It should be noted that the use of square, circular and octagonal shaped keys is only exemplary and the shapes of the keys may also be, for example, elliptical, rectangular, etc. and the surface of the keys may further be flat, rounded, etc.

Those skilled in the art will understand that the clustering arrangement scheme may still occupy a small surface area on the computing device despite the use of breaks. Furthermore, the clustering arrangement scheme, especially the shape of each group, allows users to blindly identify any group within the data input arrangement. It should be noted that the above described advantages are only exemplary and that other advantages exist for the clustering arrangement scheme. For example, the clustering arrangement scheme may be arranged to create groups of keys gathered according to the type of input. For example, keys inputting letter data may be clustered in a first group, keys inputting number data may be clustered in a second group, keys, inputting function data may be clustered in a third group, etc.

It will be apparent to those skilled in the art that various modifications may be made in the present invention, without departing from the spirit or scope of the invention. Thus, it is intended that the present invention cover the modifications and variations of this invention provided they come within the scope of the appended claims and their equivalents.

What is claimed is:

1. A data input arrangement for a mobile device, comprising:
a first group of input keys defining a first typing surface on the mobile device, the first typing surface defining a first shape;
a second group of input keys defining a second typing surface on the mobile device, the second typing surface defining a second shape different from the first shape; and
a break between the first and second groups separating the first and second groups from one another.

2. The data input arrangement of claim 1, wherein the first and second shapes is one of a wave shape, a decreasing angled shape, an increasing angled shape, and a flat shape.

3. The data input arrangement of claim 1, wherein the input keys of the first group exhibit a first uniform shape of keys and the input keys of the second group exhibit a second uniform shape of keys.

4. The data input arrangement of claim 3, wherein the first and second uniform shape of keys are one of square, rectangular, circular, elliptical, and octagonal.

5. The data input arrangement of claim 1, wherein the first group includes input keys of a first functionality and the second group includes input keys of a second functionality different from the first functionality.

6. The data input arrangement of claim 1, wherein the break is one of flat, angled and a combination thereof.

7. The data input arrangement of claim 1, further comprising:
a third group of input keys defining a third typing surface, the third typing surface defining a third shape different from the first and second shapes; and
a further break disposed between the first and third groups to separate the first and third groups from one another.

8. The data input arrangement of claim 1, wherein a width of a length of the break is one of uniform, tapering, and a combination thereof.

9. The data input arrangement of claim 1, wherein the mobile device is one of a personal computer, laptop computer, pager, cell phone, an imaging scanner, a laser scanner, a data acquisition device, a radio frequency identification reader, a barcode reader, and a wearable device.

10. A system, comprising:
a housing for a mobile device; and
a data input arrangement at least partially disposed within at least a portion of the housing, the data input arrangement including a first group of input keys defining a first typing surface on the mobile device that defines a first shape, a second group of input keys defining a second typing surface on the mobile device that defines a second shape different from the first shape, and a break between the first and second groups separating the first and second groups from one.

11. The system of claim 10, wherein the first and second shapes is one of a wave shape, a decreasing angled shape, an increasing angled shape, and a flat shape.

12. The system of claim 10, wherein the input keys of the first group exhibit a first uniform shape of keys and the input keys of the second group exhibit a second uniform shape of keys.

13. The system of claim 12, wherein the first and second uniform shape of keys are one of square, rectangular, circular, elliptical and octagonal.

14. The system of claim 10, wherein the first group includes input keys of a first functionality and the second group includes input keys of a second functionality different from the first functionality.

15. The system of claim 10, wherein the break is one of flat, angled and a combination thereof.

16. The system of claim 10, further comprising:
a third group of input keys defining a third typing surface, the third typing surface defining a third shape different from the first and second shapes; and
a further break disposed between the first and third groups to separate the first and third groups from one another.

17. The system of claim 10, wherein a width of a length of the break is one of uniform, tapering, and a combination thereof.

18. The system of claim 10, wherein the mobile device is one of a personal computer, a laptop computer, a pager, a cell phone, an imaging scanner, a laser scanner, a data acquisition device, a radio frequency identification reader, a barcode reader, and a wearable device.

19. A data input arrangement for a mobile device, comprising:
a first identification means located on a first typing surface of the mobile device for a first group of input keys;
a second identification means different from the first identification means located on a second typing surface of the mobile device for a second group of input keys; and
a separation means between the first and second groups for separating the first and second groups from one another.

20. A data input arrangement for a mobile device, comprising:
a first group of input keys defining a first typing surface on the mobile device, the first typing surface defining a wave shape;
a second group of input keys defining a second typing surface on the mobile device, the second typing surface defining a decreasing angled shape;
a third group of input keys defining a third typing surface on the mobile device, the third typing surface defining an increasing angled shape;
a fourth group of input keys defining a fourth typing surface on the mobile device, the fourth typing surface defining a flat shape; and
a break disposed between each group to separate the groups from one another.
